(19) United States
(12) Patent Application Publication
(10) Pub. No.: US 2026/0157205 A1
(43) Pub. Date: Jun. 4, 2026

(54) SEMICONDUCTOR STRUCTURE, METHOD OF FORMING THE SAME, AND ELECTRONIC DEVICE INCLUDING THE SAME

(71) Applicant: MEDIATEK INC., Hsinchu City (TW)

(72) Inventors: Pei-Haw TSAO, Hsinchu City (TW); Yu-Chih CHEN, Hsinchu City (TW); Te-Chi WONG, Hsinchu City (TW)

(21) Appl. No.: 19/372,695

(22) Filed: Oct. 29, 2025

Related U.S. Application Data
(63) Continuation-in-part of application No. 19/295,880, filed on Aug. 11, 2025.
(60) Provisional application No. 63/726,631, filed on Dec. 1, 2024.

(51) Int. Cl. H01L 23/498; H01L 21/48; H01L 23/00; H01L 23/538; H01L 25/065

(52) U.S. Cl. CPC H10W 70/66; H10W 70/095; H10W 70/611; H10W 70/635; H10W 74/15; H10W 90/00; H10W 90/724; H10W 90/733; H10W 90/734

(57) ABSTRACT

A semiconductor structure includes a first dielectric layer, a first metal layer, and a barrier layer. The first metal layer is disposed on the first dielectric layer. The barrier layer is on the upper surface and side surfaces of the first metal layer. The barrier layer includes a first via hole above the first metal layer. Moreover, the barrier layer is a nitrogen-containing layer.

### CROSS REFERENCE TO RELATED APPLICATIONS

This application is a continuation-in-part of application No. Ser. No. 19/295,880, filed on Aug. 11, 2025, which claims the benefit of U.S. Provisional Application No. 63/726,631 filed on Dec. 1, 2024, the entirety of which is incorporated by reference herein.

### BACKGROUND OF THE DISCLOSURE

### Field of the Disclosure

The present disclosure relates to a semiconductor structure, and, in particular, it relates to a redistribution layer (RDL) of a semiconductor package structure and a method of forming the same.

### Description of the Related Art

As demand increases for smaller devices with more functionality, package-on-package (PoP) technology has become increasingly popular. PoP technology vertically stacks two or more packages and minimizes the track lengths between different components, such as a controller and a memory device. This provides better electrical performance, since shorter routing of interconnections yields faster signal propagation with less noise and fewer cross-talk defects.

Redistribution layers (RDL) play an important role in package technology, as they enable fan-out of the circuits and allow for lateral communication between the chips attached to the interposer. A redistribution layer can redistribute I/O access to different parts of the chip and make it easier to add bumps to a die.

Although existing semiconductor packages are generally adequate, they are not satisfactory in every respect. For example, metal diffusion may occur between the wires in a redistribution layer, which can easily cause short-circuit failure due to dendrite growth. Moreover, expensive additives and chemical mechanical polishing (CMP) processes need to be used during the manufacture of the redistribution layer, and these can increase the cost and the difficulty of the process. Therefore, there is a need to further improve redistribution layer structures to provide better reliability.

### BRIEF SUMMARY OF THE DISCLOSURE

In accordance with some embodiments of the present disclosure, a semiconductor structure is provided. The semiconductor structure includes a first dielectric layer, a first metal layer, and a barrier layer. The first metal layer is disposed on the first dielectric layer. The barrier layer is on the upper surface and side surfaces of the first metal layer. The barrier layer includes a first via hole above the first metal layer. Moreover, the barrier layer is a nitrogen-containing layer.

In accordance with some other embodiments of the present disclosure, an electronic device is provided. The electronic device includes a substrate, an electronic unit on the substrate, and a redistribution layer disposed between the substrate and the electronic unit. The redistribution layer includes a semiconductor structure. The semiconductor structure includes a first dielectric layer, a first metal layer, and a barrier layer. The first metal layer is disposed on the first dielectric layer. The barrier layer is on the upper surface and side surfaces of the first metal layer. The barrier layer includes a first via hole above the first metal layer. Moreover, the barrier layer is a nitrogen-containing layer.

In accordance with some other embodiments of the present disclosure, a method of forming a semiconductor structure is also provided. The method includes forming a first dielectric layer. The method includes forming a first metal layer on the first dielectric layer. The method includes cleaning the first metal layer. The method includes forming a barrier layer on side surfaces and the upper surface of the first metal layer, wherein the barrier layer is a nitrogen-containing layer. The method includes forming a first via hole above the first metal layer.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1A to 1H are cross-sectional diagrams of an exemplary semiconductor structure in different stages of the manufacturing process in accordance with some embodiments of the present disclosure;

FIG. 2A. to 2C are cross-sectional diagrams of an exemplary semiconductor structure in different stages of the manufacturing process in accordance with some embodiments of the present disclosure;

FIG. 3A. to 3D are cross-sectional diagrams of an exemplary semiconductor structure in different stages of the manufacturing process in accordance with some embodiments of the present disclosure;

FIGS. 4 to 9 are cross-sectional diagrams of an exemplary electronic device in different stages of the manufacturing process in accordance with some embodiments of the present disclosure.

### DETAILED DESCRIPTION OF THE INVENTION

The semiconductor structure and the method of forming the same according to the present disclosure is described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “between the first value and the second value” means that the range includes the first value, the second value, and other values in between.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with the embodiments of the present disclosure, a semiconductor structure is provided. The semiconductor structure can be a redistribution layer (RDL) structure. The semiconductor structure includes a barrier layer disposed on the side surfaces of the metal layer. The barrier layer can reduce metal diffusion occurring between the metal layers in the redistribution layer, thereby improving the reliability of the semiconductor structure. Moreover, with the specific configuration of the barrier layer and the dielectric layer, the process cost and difficulty of the semiconductor structure can also be decreased.

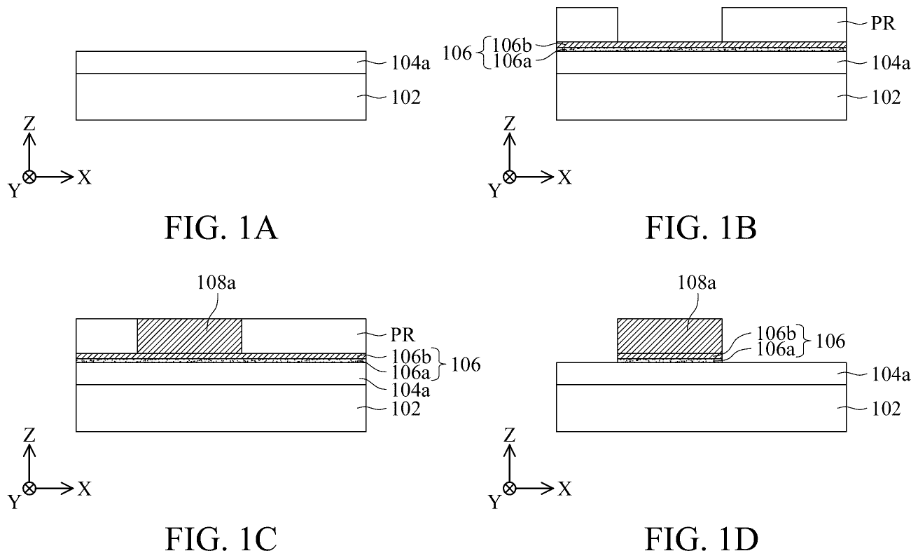

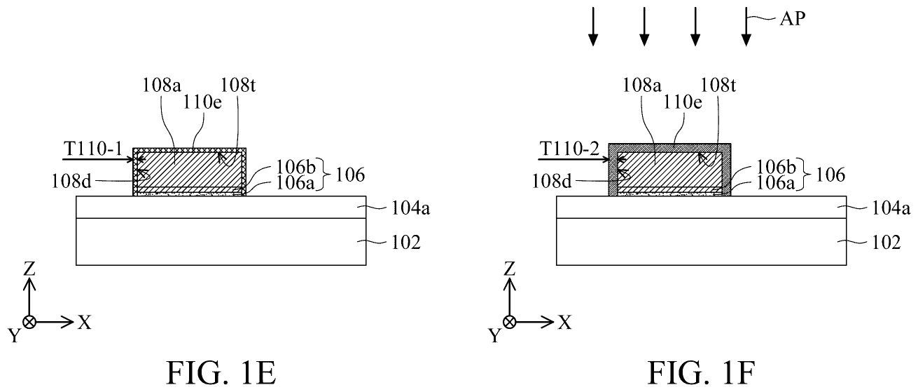

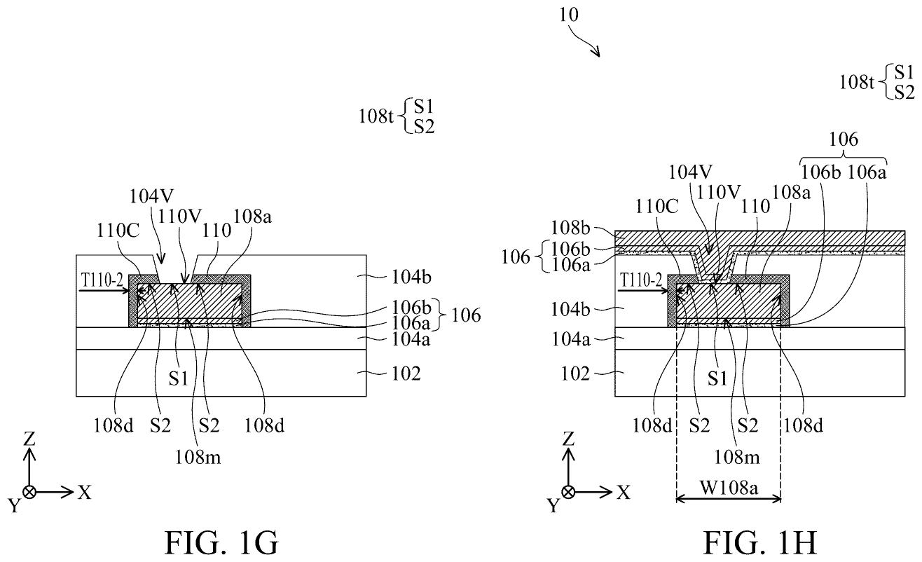

Please refer to FIGS. 1A to 1H, which are cross-sectional diagrams of an exemplary semiconductor structure 10 in different stages of the manufacturing process in accordance with some embodiments of the present disclosure. In accordance with some embodiments, additional operations may be provided before, during, and/or after the method of forming the semiconductor structure 10. In accordance with some embodiments, some of the operations described may be replaced or deleted. In accordance with some embodiments, the order of the operations may be interchangeable. Furthermore, some elements of the semiconductor structure 10 may be omitted in the figure for clarity, and only some elements are schematically illustrated. In accordance with some embodiments, additional features may be added to the semiconductor structure 10 described below. In accordance with some other embodiments, some features of the semiconductor structure 10 described below may be replaced or omitted.

As shown in FIG. 1A, in accordance with some embodiments, a substrate 102 is provided. The substrate 102 may serve as a carrier substrate. In accordance with some embodiments, the substrate 102 may include a glass carrier substrate, a ceramic carrier substrate, a carrier tape, another suitable structure, or a combination thereof, but it is not limited thereto.

Moreover, a first dielectric layer 104a may be formed on the substrate 102. The first dielectric layer 104a may be formed of organic polymer materials. In accordance with some embodiments, the material of the first dielectric layer 104a includes polyimide (PI), polybenzoxazole (PBO), benzocyclobutene (BCB), another suitable polymeric dielectric material, or a combination thereof, but it is not limited thereto. In accordance with some embodiments, the first dielectric layer 104a is formed by a spin coating process, a chemical vapor deposition (CVD) process, another applicable process, or a combination thereof. The chemical vapor deposition process may include, for example, a low pressure chemical vapor deposition (LPCVD), a low temperature chemical vapor deposition (LTCVD), a rapid thermal chemical vapor deposition (RTCVD), a plasma enhanced chemical vapor deposition (PECVD) or an atomic layer deposition (ALD), etc.

Then, referring to FIG. 1B, a seed layer 106 may be formed on the first dielectric layer 104a, in accordance with some embodiments. The seed layer 106 may have a composite structure, for example, including a first sub-layer 106a and a second sub-layer 106b formed on the first sub-layer 106a. In accordance with some embodiments, the first sub-layer 106a and the second sub-layer 106b are a titanium (Ti) layer and a copper (Cu) layer, respectively. In accordance with some embodiments, the material of the seed layer 106 may include tantalum (Ta), gold (Au), nickel (Ni), aluminum (Al), another suitable conductive material, or a combination thereof, but it is not limited thereto. In accordance with some embodiments, the seed layer 106 is formed by a physical vapor deposition (PVD) process, an electroplating process, an electroless plating process, another applicable process, or a combination thereof. The physical vapor deposition process may include, for example, a sputtering process, an evaporation process, or a pulsed laser deposition, etc.

Then, a photoresist layer PR may be formed on the seed layer 106. In accordance with some embodiments, the photoresist layer PR is formed through a coating and curing process, a lamination process, another applicable process, or a combination thereof. As shown in FIG. 1B, a portion of the photoresist layer PR may be removed to form a patterned photoresist layer PR. The patterned photoresist layer PR can define the profile of a subsequently formed conductive layer 108a. The photoresist layer PR may be a positive photoresist material or a negative photoresist material. In accordance with some embodiments, the photoresist material is patterned through one or more photolithography processes and/or etching processes to form the patterned photoresist layer PR. In accordance with some embodiments, the photolithography process may include photoresist coating (e.g., spin coating), soft baking, hard baking, mask alignment, exposure, post-exposure baking, photoresist development, cleaning and drying, etc. The etching process may include a dry etching process or a wet etching process.

Referring to FIG. 1C, a first metal layer 108a is formed on the first dielectric layer 104a and the seed layer 106. Specifically, the first metal layer 108a may be formed using the patterned photoresist layer PR as a mask. In accordance with some embodiments, the material of the first metal layer 108a includes copper (Cu), titanium (Ti), aluminum (Al), tungsten (W), silver (Ag), gold (Au), tin (Sn), molybdenum (Mo), chromium (Cr), nickel (Ni), platinum (Pt), cobalt (Co), tantalum (Ta), ruthenium (Ru), alloys of the aforementioned metals, another suitable conductive material, or a combination thereof, but it is not limited thereto. In accordance with some embodiments, the material of the first metal layer 108a includes copper. In accordance with some embodiments, the first metal layer 108a is formed by a physical vapor deposition (PVD) process, an electroplating process, an electroless plating process, another applicable process, or a combination thereof.

Then, referring to FIG. 1D, the photoresist layer PR and a portion of the seed layer 106 may be removed. Specifically, in accordance with some embodiments, the portion of the seed layer 106 covered by the photoresist layer PR is removed along with the photoresist layer PR; and another portion of the seed layer 106 covered by the first metal layer 108a remains. In accordance with some embodiments, the photoresist layer PR is removed through a wet stripping process, a plasma ashing process, another applicable process, or a combination thereof.

Referring to FIG. 1E, an elemental layer 110e is formed to cover the first metal layer 108a. Specifically, the elemental layer 110e covers the side surfaces 108d and the upper surface 108t of the first metal layer 108a. In accordance with some embodiments, the elemental layer 110e is conformally formed on the side surfaces 108d and the upper surface 108t of the first metal layer 108a. In accordance with some embodiments, the elemental layer 110e is also formed on the side surfaces of the seed layer 106. In accordance with some embodiments, the material of the elemental layer 110e includes tin (Sn). In accordance with some embodiments, the elemental layer 110e is formed by an electroless plating process, another applicable process, or a combination thereof. In accordance with some embodiments, the thickness T110-1 of the elemental layer 110e is less than or equal to 0.1 μm, for example, it may be 0.01 μm, 0.02 μm, 0.03 μm, 0.04 μm, 0.05 μm, 0.06 μm, 0.07 μm, 0.08 μm, 0.09 μm, but it is not limited thereto. In particular, the thickness T110-1 of the elemental layer 110e may be controlled to be less than or equal to 0.1 μm so that the subsequent process of removing the elemental layer 110e that remains after the annealing process can be omitted. The process of forming the semiconductor structure can be simplified and the cost can also be reduced.

Then, referring to FIG. 1F, an annealing process AP is performed to form a barrier layer 110 covering the upper surface 108t and the side surfaces 108d of the first metal layer 108. In accordance with some embodiments, the barrier layer 110 may also cover the side surfaces of the seed layer 106. In accordance with some embodiments, the barrier layer 110 is in direct contact with the upper surface 108t and the side surfaces 108d of the first metal layer 108. The barrier layer 110 includes an intermetallic compound formed by the reaction of the first metal layer 108a and the elemental layer 110e. In accordance with some embodiments, the barrier layer 110 consists of an intermetallic compound formed by the reaction of the first metal layer 108a and the elemental layer 110e. In accordance with some embodiments, the intermetallic compound includes a copper-tin compound having a chemical formula of CuxSny, and x and y are positive integers. Specifically, in accordance with some embodiments, the copper-tin compound includes Cu₃Sn, Cu₆Sn₅, or a combination thereof. In particular, the barrier layer 110 can reduce metal diffusion occurring between the metal layers in the semiconductor structure (e.g., redistribution layer) and can prevent Kirkendall void formation, thereby improving the reliability of the semiconductor structure 10.

In accordance with some embodiments, the thickness T110-2 of the barrier layer 110 is between 0.05 μm and 0.35 μm, for example, it may be 0.1 μm, 0.15 μm, 0.2 μm, 0.25 μm, or 0.3 μm, but it is not limited thereto. In accordance with some embodiments, the thickness T110-2 of the barrier layer 110 is greater than the thickness T110-1 of the elemental layer 110e. For example, in accordance with some embodiments, a ratio of the thickness T110-2 of the barrier layer 110 to the thickness T 110-1 of the elemental layer 110e is about 3:1.

Moreover, in accordance with some embodiments, the annealing process AP is performed at a temperature between 150° C. and 200° C., for example, 155° C., 160° C., 165° C., 170° C., 175° C., 180° C., 185° C., 190° C., or 195° C., but it is not limited thereto. In accordance with some embodiments, the annealing process AP is performed for 1 hour to 8 hours, for example, 1.5 hours, 2 hours, 2.5 hours, 3 hours, 3.5 hours, 4 hours, 4.5 hours, 5 hours, 5.5hours, 6 hours, 6.5 hours, 7 hours, or 7.5 hours, but it is not limited thereto.

As described above, in accordance with some embodiments, the entire elemental layer 110e reacts with the first metal layer 108a, and no elemental layer 110e is left after the annealing process AP is performed. In this case, the subsequent process of removing the remaining elemental layer 110e is omitted. Nevertheless, in accordance with some other embodiments, the thickness T110-1 of the elemental layer 110e formed on the first metal layer 108a (e.g., the step shown in FIG. 1E) may be greater than 0.1 μm, and the method may further include a step of removing the elemental layer 110e that remains after the annealing process AP. For example, the remaining elemental layer 110e may be removed using a dry etching process or a wet etching process.

Next, referring to FIG. 1G, a first via hole 110V is formed above the first metal layer 108a. Specifically, in accordance with some embodiments, a second dielectric layer 104b is formed on the first dielectric layer 104a to cover the first metal layer 108a, and then a portion of the barrier layer 110 is removed to form the first via hole 110V above the first metal layer 108a. In accordance with some embodiments, the second dielectric layer 104b may be formed on the first dielectric layer 104a and cover the barrier layer 110, and a portion of the barrier layer 110 contacting the first metal layer 108a may be removed. Moreover, as shown in FIG. 1G, a portion of the second dielectric layer 104b is also removed to form a second via hole 104V, and the second via hole 104V is connected to the first via hole 110V.

The second dielectric layer 104b may be formed of organic polymer materials. In accordance with some embodiments, the material of the second dielectric layer 104b includes polyimide (PI), polybenzoxazole (PBO), benzocyclobutene (BCB), another suitable polymeric dielectric material, or a combination thereof, but it is not limited thereto. In accordance with some embodiments, the second dielectric layer 104b is formed by a spin coating process, a chemical vapor deposition (CVD) process, another applicable process, or a combination thereof.

In addition, portions of the barrier layer 110 and second dielectric layer 104b are removed through one or more photolithography processes and/or etching processes to form the first via hole 110V and the second via hole 104V. In accordance with some embodiments, the first via hole 110V and the second via hole 104V may be formed at the same step. In particular, since the second dielectric layer 104b is photosensitive, the second via hole 104V can be formed without providing an additional photoresist mask during the photolithography process.

In accordance with some embodiments, after the first via hole 110V and the second via hole 104V are formed, a first portion S1 of the upper surface 108t of the first metal layer 108a overlapping the first via hole 110V has a first roughness, a lower surface 108m of the first metal layer 108a has a second roughness, and the first roughness is different from the second roughness. For example, the first roughness is greater than the second roughness, in accordance with some embodiments. Moreover, in accordance with some embodiments, a second portion S2 of the upper surface 108t of the first metal layer 108a not overlapping the first via hole 110V has a third roughness, and the first roughness is different from the third roughness. For example, the first roughness is greater than the third roughness, in accordance with some embodiments. Furthermore, the aforementioned first portion S1 of the upper surface 108t of the first metal layer 108a refers to the portion of the upper surface 108t overlapping the bottom of the first via hole 110V, for example, in the normal direction of the substrate 102 (e.g., the Z direction in the drawing). The aforementioned second portion S2 of the upper surface 108t of the first metal layer 108a refers to the portion of the upper surface 108t not overlapping the bottom of the first via hole 110V, for example, in the normal direction of the substrate 102 (e.g., the Z direction in the drawing).

Then, referring to FIG. 1H, a second metal layer 108b is formed in the first via hole 110V and the second via hole 104V. The second metal layer 108b disposed in the first via hole 110V and the second via hole 104V can serve as a conductive via electrically connected to the first metal layer 108a. In accordance with some embodiments, a portion of the second metal layer 108b is disposed on the upper surface of the second dielectric layer 104b, and another portion of the second metal layer 108b penetrates the first via hole 110V and the second via hole 104V. In accordance with some embodiments, before the second metal layer 108b is formed, a seed layer 106 may be formed on the upper surface of the second dielectric layer 104b and extend into the first via hole 110V and the second via hole 104V. In accordance with some embodiments, the material of the second metal layer 108b includes copper (Cu), titanium (Ti), aluminum (Al), tungsten (W), silver (Ag), gold (Au), tin (Sn), molybdenum (Mo), chromium (Cr), nickel (Ni), platinum (Pt), cobalt (Co), tantalum (Ta), ruthenium (Ru), alloys of the aforementioned metals, another suitable conductive material, or a combination thereof, but it is not limited thereto. In accordance with some embodiments, the material of the second metal layer 108b includes copper. In accordance with some embodiments, the second metal layer 108b is formed by a physical vapor deposition (PVD) process, an electroplating process, an electroless plating process, another applicable process, or a combination thereof.

As shown in FIG. 1H, the semiconductor structure 10 formed by the aforementioned method includes the first dielectric layer 104a, the first metal layer 108a, and the barrier layer 110. The first metal layer 108a is disposed on the first dielectric layer 104a. The barrier layer 110 covers the upper surface 108t and the side surfaces 108d of the first metal layer 108a and includes a first via hole 110V above the first metal layer 108a. Moreover, the barrier layer 110 includes an intermetallic compound. In accordance with some embodiments, the intermetallic compound includes a copper-tin compound having a chemical formula of CuxSny, and x and y are positive integers. Specifically, in accordance with some embodiments, the copper-tin compound includes Cu₃Sn, Cu₆Sn₅, or a combination thereof. In accordance with some embodiments, the thickness T110-2 of the barrier layer 110 is between 0.05 μm and 0.35 μm, for example, it may be 0.1 μm, 0.15 μm, 0.2 μm, 0.25 μm, or 0.3 μm, but it is not limited thereto.

In accordance with some embodiments, the semiconductor structure 10 further includes the second dielectric layer 104b disposed on the first dielectric layer 104a. The second dielectric layer 104b includes the second via hole 104V connecting the first via hole 110V. In accordance with some embodiments, the semiconductor structure 10 further includes the second metal layer 108b disposed in the first via hole 110V and the second via hole 104V. The second metal layer 108b is electrically connected to the first metal layer 108a through the first via hole 110V and the second via hole 104V. In accordance with some embodiments, the semiconductor structure 10 further includes the seed layer 106 disposed between the first dielectric layer 104a and the lower surface 108m of the first metal layer 108a. In accordance with some embodiments, the semiconductor structure 10 further includes the seed layer 106 disposed between the second metal layer 108b and the second dielectric layer 104b.

In accordance with some embodiments, the first portion S1 of the upper surface 108t of the first metal layer 108a overlapping the first via hole 110V has the first roughness, the lower surface 108m of the first metal layer 108a has the second roughness, and the first roughness is different from the second roughness. For example, the first roughness is greater than the second roughness, in accordance with some embodiments. Moreover, in accordance with some embodiments, the second portion S2 of the upper surface 108t of the first metal layer 108a not overlapping the first via hole 110V has the third roughness, and the first roughness is different from the third roughness. For example, the first roughness is greater than the third roughness, in accordance with some embodiments.

In accordance with some embodiments, the first metal layer 108a and the second metal layer 108b serve as the wiring trace of the redistribution layer. Moreover, in accordance with some embodiments, the width W108a of the first metal layer 108a is less than or equal to 5 μm, for example, it may be 4.5 μm, 4 μm, 3.5 μm, 3 μm, 2.5 μm, 2 μm, 1.5 μm, or 1 μm, but it is not limited thereto. In accordance with some embodiments, the gap between the adjacent first metal layers 108a is less than or equal to 5 μm, for example, it may be 4.5 μm, 4 μm, 3.5 μm, 3 μm, 2.5 μm, 2 μm, 1.5 μm, or 1 μm, but it is not limited thereto.

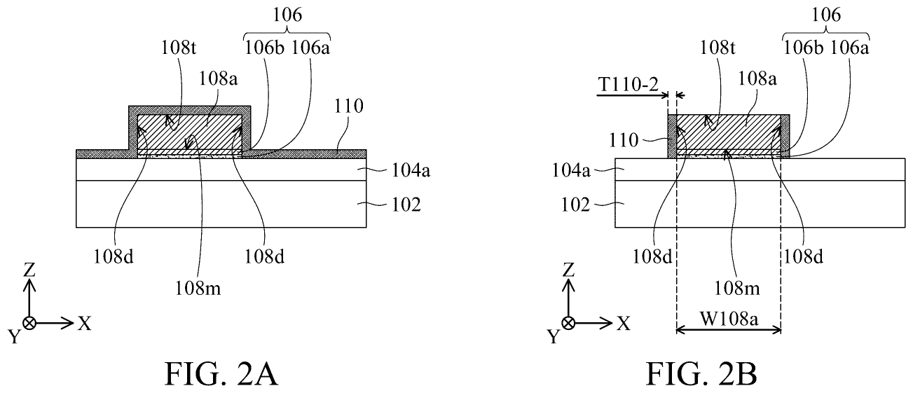

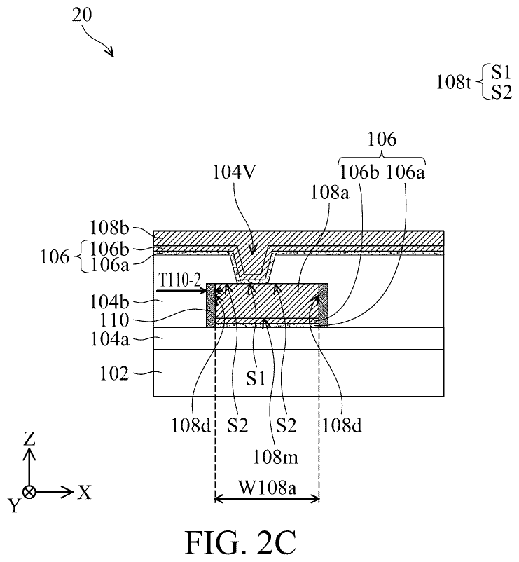

Next, please refer to FIGS. 2A to 2C, which are cross-sectional diagrams of an exemplary semiconductor structure 20 in different stages of the manufacturing process in accordance with some other embodiments of the present disclosure. It should be understood that the same or similar components or elements in above and below contexts are represented by the same or similar reference numerals. The materials, manufacturing methods and functions of these components or elements are the same or similar to those described above, and thus will not be repeated in the following description.

Specifically, the step shown in FIG. 2A can be followed by the step shown in FIG. 1D. That is, the method of forming the semiconductor structure 20 may include the following steps: providing a substrate 102; forming a first dielectric layer 104a on the substrate 102; forming a seed layer 106 on the first dielectric layer 104a; forming a photoresist layer PR on the seed layer 106; forming a first metal layer 108a on the first dielectric layer 104a; and removing the photoresist layer PR and a portion of the seed layer 106.

Then, as shown in FIG. 2A, in this embodiment, a barrier layer 110 is formed to cover the upper surface 108t and the side surfaces 108d of the first metal layer 108a. The barrier layer 110 may be conformally formed on the side surfaces 108d and the upper surface 108t of the first metal layer 108a. In accordance with some embodiments, the barrier layer 110 may also be formed on the side surfaces of the seed layer 106 and the upper surface of the first dialectic layer 104a. In this embodiment, the material of the barrier layer 110 includes titanium (Ti), palladium (Pd), gold (Au), nickel (Ni), tin (Sn), or a combination thereof. In one embodiment, the material of the barrier layer 110 includes titanium. The barrier layer 110 may be formed by a physical vapor deposition (PVD) process, an electroplating process, an electroless plating process, another applicable process, or a combination thereof.

Then, referring to FIG. 2B, portions of the barrier layer 110 disposed on the upper surface 108t of the first metal layer 108a and the first dielectric layer 104a are removed. The upper surface 108t of the first metal layer 108a may be exposed. In this embodiment, the thickness T110-2 of the barrier layer 110 is between 0.05 μm and 0.35 μm, for example, it may be 0.1 μm, 0.15 μm, 0.2 μm, 0.25 μm, or 0.3 μm, but it is not limited thereto. Moreover, the portions of the barrier layer 110 disposed on the upper surface 108t of the first metal layer 108a and the first dielectric layer 104a may be removed using a dry etching process or a wet etching process.

Next, referring to FIG. 2C, a second via hole 104V is formed above the first metal layer 108a. Specifically, a second dielectric layer 104b may be formed on the first dielectric layer 104a to cover the first metal layer 108a, and then a portion of the second dielectric layer 104b is removed to form a second via hole 104V above the first metal layer 108a. In particular, since the second dielectric layer 104b is photosensitive, the second via hole 104V can be formed without providing an additional photoresist mask during the photolithography process.

In this embodiment, after the second via hole 104V are formed, a first portion S1 of the upper surface 108t of the first metal layer 108a overlapping the second via hole 104V may have a first roughness, a lower surface 108m of the first metal layer 108a may have a second roughness, and the first roughness may be different from the second roughness. For example, the first roughness may be greater than the second roughness. Moreover, a second portion S2 of the upper surface 108t of the first metal layer 108a not overlapping the second via hole 104V may have a third roughness, and the first roughness may be different from the third roughness. For example, the first roughness may be greater than the third roughness. Furthermore, the aforementioned first portion S1 of the upper surface 108t of the first metal layer 108a refers to the portion of the upper surface 108t overlapping the bottom of the second via hole 104V, for example, in the normal direction of the substrate 102 (e.g., the Z direction in the drawing). The aforementioned second portion S2 of the upper surface 108t of the first metal layer 108a refers to the portion of the upper surface 108t not overlapping the bottom of the second via hole 104V, for example, in the normal direction of the substrate 102 (e.g., the Z direction in the drawing).

As shown in FIG. 2C, a second metal layer 108b then is formed in the second via hole 104V. The second metal layer 108b disposed in the second via hole 104V can serve as a conductive via electrically connected to the first metal layer 108a. A portion of the second metal layer 108b may be disposed on the upper surface of the second dielectric layer 104b, and another portion of the second metal layer 108b may penetrate the second via hole 104V. Before the second metal layer 108b is formed, a seed layer 106 may be formed on the upper surface of the second dielectric layer 104b and extend into the second via hole 104V.

The semiconductor structure 20 formed by the aforementioned method includes the first dielectric layer 104a, the first metal layer 108a, and the barrier layer 110. The first metal layer 108a is disposed on the first dielectric layer 104a. The barrier layer 110 covers the side surfaces 108d of the first metal layer 108a and includes a second via hole 104V above the first metal layer 108a. Moreover, the material of the barrier layer 110 includes titanium (Ti), palladium (Pd), gold (Au), nickel (Ni), tin (Sn), or a combination thereof. In accordance with some embodiments, the thickness T110-2 of the barrier layer 110 is between 0.05 μm and 0.35 μm, for example, it may be 0.1 μm, 0.15 μm, 0.2 μm, 0.25 μm, or 0.3 μm, but it is not limited thereto.

In accordance with some embodiments, the semiconductor structure 20 further includes the second dielectric layer 104b disposed on the first dielectric layer 104a. The second dielectric layer 104b includes the second via hole 104V. In accordance with some embodiments, the semiconductor structure 20 further includes the second metal layer 108b disposed in the second via hole 104V. The second metal layer 108b is electrically connected to the first metal layer 108a through the second via hole 104V. In accordance with some embodiments, the semiconductor structure 20 further includes the seed layer 106 disposed between the first dielectric layer 104a and the lower surface 108m of the first metal layer 108a. In accordance with some embodiments, the semiconductor structure 20 further includes the seed layer 106 disposed between the second metal layer 108b and the second dielectric layer 104b.

The first metal layer 108a and the second metal layer 108b may serve as the wiring trace of the redistribution layer. Moreover, in accordance with some embodiments, the width W108a of the first metal layer 108a is less than or equal to 5 μm, for example, it may be 4.5 μm, 4 μm, 3.5 μm, 3 μm, 2.5 μm, 2 μm, 1.5 μm, or 1 μm, but it is not limited thereto. In accordance with some embodiments, the gap between the adjacent first metal layers 108a is less than or equal to 5 μm, for example, it may be 4.5 μm, 4 μm, 3.5 μm, 3 μm, 2.5 μm, 2 μm, 1.5 μm, or 1 μm, but it is not limited thereto.

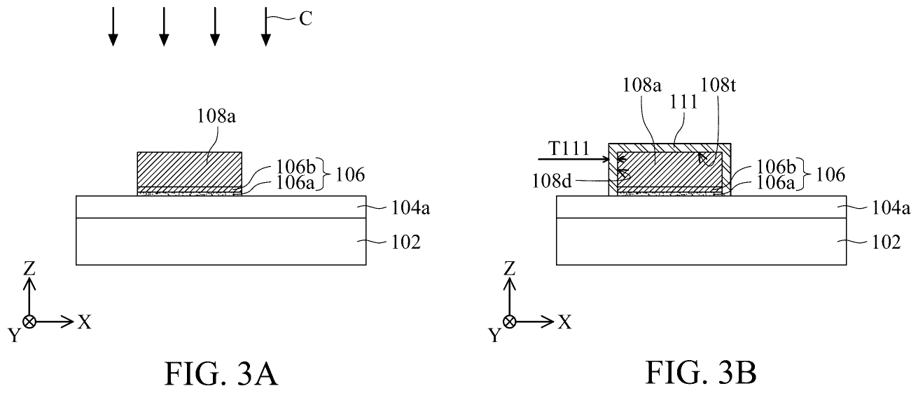

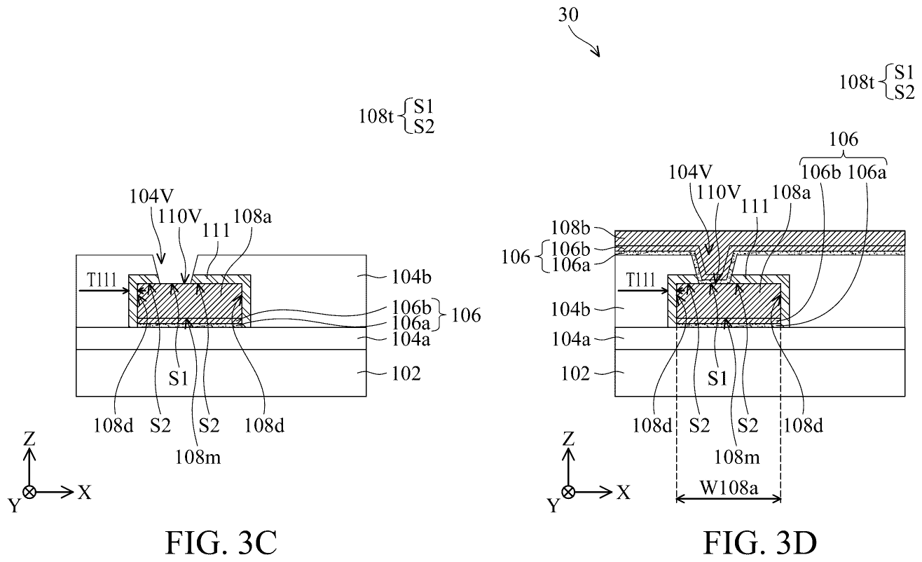

Next, please refer to FIGS. 3A to 3C, which are cross-sectional diagrams of an exemplary semiconductor structure 30 in different stages of the manufacturing process in accordance with some other embodiments of the present disclosure. It should be understood that the same or similar components or elements in above and below contexts are represented by the same or similar reference numerals. The materials, manufacturing methods and functions of these components or elements are the same or similar to those described above, and thus will not be repeated in the following description.

Specifically, the step shown in FIG. 3A can be followed by the step shown in FIG. 1D. That is, the method of forming the semiconductor structure 30 may include the following steps: providing a substrate 102; forming a first dielectric layer 104a on the substrate 102; forming a seed layer 106 on the first dielectric layer 104a; forming a photoresist layer PR on the seed layer 106; forming a first metal layer 108a on the first dielectric layer 104a; and removing the photoresist layer PR and a portion of the seed layer 106.

After the step of removing the photoresist layer PR and a portion of the seed layer 106, a cleaning step C of cleaning the first metal layer 108a may be performed, as shown in FIG. 3A. In some embodiments, the cleaning step C may include removing the naturally formed oxide on the upper surface 108t and side surfaces 108d of the first metal layer 108a using a wet etching process or a plasma etching process, but the present disclosure is not limited thereto.

A step of forming a barrier layer 111 may be performed after the cleaning step C. The barrier layer forming step may include a plasma treatment using a N₂ plasma or an atomic layer deposition (ALD) process employing a nitrogen source such as N₂ or NH₃ to directly form the barrier layer. In some embodiments, in the barrier layer 111 forming step, the barrier layer 111 is formed to cover the first metal layer 108a. Specifically, the barrier layer 111 covers the side surfaces 108d and the upper surface 108t of the first metal layer 108a. In some embodiments, in the barrier layer 111 forming step, the barrier layer 111 is formed from the first metal layer 108a on the side surfaces 108d and the upper surface 108t of the first metal layer 108a, as shown in FIG. 3B. In some embodiments, the thickness T111 of the barrier layer 111 is greater than 10 nm. In some embodiments, the thickness T111 of the barrier layer 111 may be between 10 nm and 30 nm, 15 nm and 25 nm, or 20 nm, but it is not limited thereto.

The barrier layer 111 may be a nitrogen-containing layer. In some embodiments, the nitrogen-containing layer may include a copper nitride, such as Cu₄N, Cu₃N, or a combination thereof. In some embodiments, the nitrogen content of the barrier layer 111 may be from 5 to 15 wt %. In the present disclosure, the nitrogen content of the barrier layer 111 may be measured by TEM EDX Mapping.

Next, referring to FIG. 3C, a first via hole 110V is formed above the first metal layer 108a. Specifically, in accordance with some embodiments, a second dielectric layer 104b is formed on the first dielectric layer 104a to cover the first metal layer 108a, and then a portion of the barrier layer 111 is removed to form the first via hole 110V above the first metal layer 108a. In accordance with some embodiments, the second dielectric layer 104b may be formed on the first dielectric layer 104a and cover the barrier layer 111, and a portion of the barrier layer 111 contacting the first metal layer 108a may be removed. Moreover, as shown in FIG. 3C, a portion of the second dielectric layer 104b is also removed to form a second via hole 104V, and the second via hole 104V is connected to the first via hole 110V.

In addition, portions of the barrier layer 111 and second dielectric layer 104b are removed through one or more photolithography processes and/or etching processes to form the first via hole 110V and the second via hole 104V. In accordance with some embodiments, the first via hole 110V and the second via hole 104V may be formed at the same step. In particular, since the second dielectric layer 104b is photosensitive, the second via hole 104V can be formed without providing an additional photoresist mask during the photolithography process.

Then, referring to FIG. 3D, a second metal layer 108b is formed in the first via hole 110V and the second via hole 104V. The second metal layer 108b disposed in the first via hole 110V and the second via hole 104V can serve as a conductive via electrically connected to the first metal layer 108a. In accordance with some embodiments, a portion of the second metal layer 108b is disposed on the upper surface of the second dielectric layer 104b, and another portion of the second metal layer 108b penetrates the first via hole 110V and the second via hole 104V. In accordance with some embodiments, before the second metal layer 108b is formed, a seed layer 106 may be formed on the upper surface of the second dielectric layer 104b and extend into the first via hole 110V and the second via hole 104V.

As shown in FIG. 3D, the semiconductor structure 30 formed by the aforementioned method includes the first dielectric layer 104a, the first metal layer 108a, and the barrier layer 111. The first metal layer 108a is disposed on the first dielectric layer 104a. The barrier layer 111 covers the upper surface 108t and the side surfaces 108d of the first metal layer 108a and includes a first via hole 110V above the first metal layer 108a. Moreover, the barrier layer 111 may be a nitrogen-containing layer. In some embodiments, the nitrogen-containing layer may include a copper nitride, such as Cu₄N, Cu₃N, or a combination thereof. In some embodiments, the nitrogen content of the barrier layer 111 is within a range of 5 to 15 wt %. In accordance with some embodiments, the thickness T111 of the barrier layer 111 is greater than 10 nm. In some embodiments, the thickness T111 of the barrier layer 111 may be between 10 nm and 30 nm, 15 nm and 25 nm, or 20 nm, but it is not limited thereto.

In accordance with some embodiments, the semiconductor structure 30 further includes the second dielectric layer 104b disposed on the first dielectric layer 104a. The second dielectric layer 104b includes the second via hole 104V connecting the first via hole 110V. In accordance with some embodiments, the semiconductor structure 30 further includes the second metal layer 108b disposed in the first via hole 110V and the second via hole 104V. The second metal layer 108b is electrically connected to the first metal layer 108a through the first via hole 110V and the second via hole 104V. In accordance with some embodiments, the semiconductor structure 30 further includes the seed layer 106 disposed between the first dielectric layer 104a and the lower surface 108m of the first metal layer 108a. In accordance with some embodiments, the semiconductor structure 30 further includes the seed layer 106 disposed between the second metal layer 108b and the second dielectric layer 104b.

In accordance with some embodiments, the first metal layer 108a and the second metal layer 108b serve as the wiring trace of the redistribution layer. Moreover, in accordance with some embodiments, the width W108a of the first metal layer 108a is less than or equal to 5 μm, for example, it may be 4.5 μm, 4 μm, 3.5 μm, 3 μm, 2.5 μm, 2 μm, 1.5 μm, or 1 μm, but it is not limited thereto. In accordance with some embodiments, the gap between the adjacent first metal layers 108a is less than or equal to 5 μm, for example, it may be 4.5 μm, 4 μm, 3.5 μm, 3 μm, 2.5 μm, 2 μm, 1.5 μm, or 1 μm, but it is not limited thereto.

In accordance with the embodiments of the present disclosure, the provided method of forming the semiconductor structure can be applied, for example, to a wafer-level package (WLP) or panel-level package (PLP) process, and a chip-first process or a chip-last/RDL first process may be used. Furthermore, the semiconductor structure referred to in the present disclosure may be applied to an electronic device, and the electronic device may include package-on-package (POP), System on Chip (SoC), System in Package (SiP), Chip on Wafer on Substrate (CoWoS) packaging, System on Integrated Chip (SoIC), Antenna in Package (AiP), Co-Packaged Optics (CPO), Micro Electro Mechanical System (MEMS) or a combination thereof, but the present disclosure is not limited thereto.

FIGS. 3 to 8 are cross-sectional diagrams of an exemplary electronic device 1 in different stages of the manufacturing process in accordance with some embodiments of the present disclosure. It should be understood that, for clarity of explanation, some components of the electronic device 1 may be omitted in the drawings, and only some components are schematically illustrated. In accordance with some embodiments, additional features may be added to the electronic device 1 described below.

Specifically, the electronic device 1 may be formed based on the aforementioned semiconductor structure as a redistribution layer. For example, the electronic device 1 can be applied to the a structure of a Chip on Wafer on Substrate (CoWoS) package.

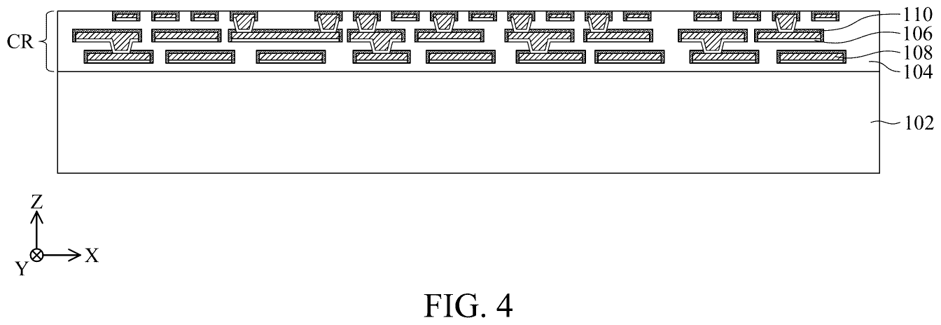

As shown in FIG. 4, a substrate 102 is provided, and a redistribution layer CR is formed on the substrate 102. In accordance with some embodiments, the redistribution layer CR has the structure based on the aforementioned semiconductor structure 10, but it is not limited thereto. The redistribution layer CR may also have the structure based on the aforementioned semiconductor structure 20. The redistribution layer CR may include a dielectric layer 104 and a plurality of metal layers 108 formed in the dielectric layer 104. The redistribution layer CR includes a barrier layer 110 covering the upper surface 108t and the side surfaces 108d of the metal layer 108. The redistribution layer CR may also include a seed layer 106 disposed between the lower surface of the metal layer 108 and the dielectric layer 104. In accordance with some embodiments, portions of the metal layer 108 may serve as conductive pads (e.g., under-bump metallization (UBM)) for electrical connection with the chips.

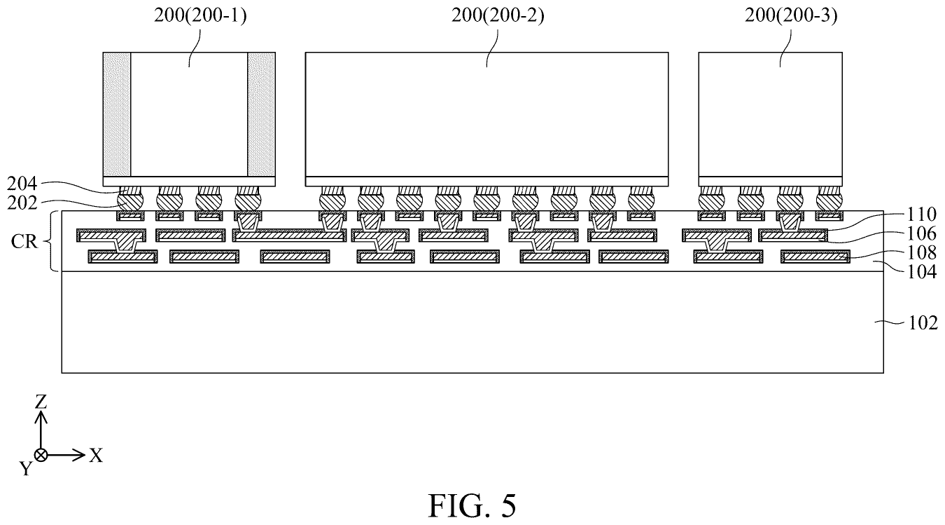

Referring to FIG. 5, a plurality of electronic units 200 may be provided on the redistribution layer CR. In accordance with some embodiments, the electronic unit 200 may include, for example, a known-good die (KGD), an integrated circuit chip (IC), or a surface mount device (SMD), a dummy die, a diode or another suitable electronic component, but it is not limited thereto. Specifically, in accordance with some embodiments, the electronic unit 200 may include a system on a chip (SoC), a dynamic random access memory, a high-bandwidth memory (HBM), a photonic integrated circuit, an application-specific integrated circuit, or another logic integrated circuit. In accordance with some other embodiments, the electronic units 200 are different types of electronic units. For clarity, different electronic units 200 are labeled as the electronic units 200-1, 200-2 and 200-3 in FIG. 4. For example, in accordance with some embodiments, the electronic unit 200-1 is a high-bandwidth memory, the electronic unit 200-2 is a system on a chip, and the electronic unit 200-3 is a dummy die, but the present disclosure is not limited thereto.

Moreover, the electronic units 200 may be electrically connected to the redistribution layer CR through a plurality of first connecting elements 202. In accordance with some embodiments, the electronic unit 200 includes a plurality of conductive elements 204, which may serve as contact pads, and the conductive elements 204 may be electrically connected to the first connecting elements 202. In accordance with some embodiments, the first connecting element 202 is disposed between the conductive element 204 of the electronic unit 200 and the metal layer 108 of the redistribution layer CR. In accordance with some embodiments, the material of the first connecting element 202 may include tin, silver, lead-free tin, copper, gallium, nickel, gold, another suitable material, or a combination thereof, but it is not limited thereto. In accordance with some embodiments, the first connecting element 202 may be bonded onto the redistribution layer CR through a reflow process, a fusion bonding process, a hybrid bonding process, a metal-to-metal bonding process, another applicable process, or a combination thereof. The electronic units 200 thereby may be bonded to the redistribution layer CR.

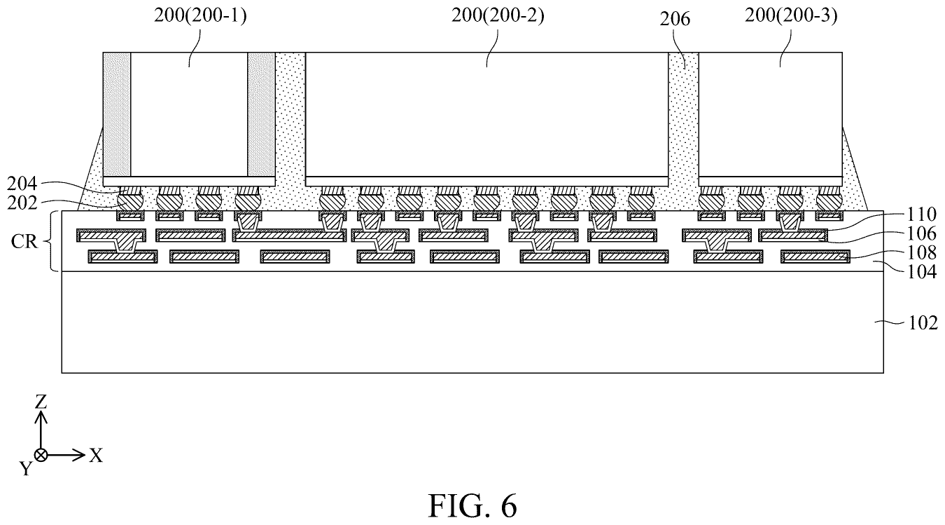

Referring to FIG. 6, a first insulating layer 206 may be formed to surround the first connecting elements 202 and the conductive elements 204 and may be used to fill the gaps between the electronic unit 200 and the redistribution layer CR to provide structural support. The first insulating layer 206 also may be disposed on the side surfaces of the electronic unit 200. In accordance with some embodiments, the first insulating layer 206 may be an encapsulation material or an underfill, which can reduce the effect of water and oxygen in the external environment on the first connecting elements 202 and/or the conductive elements 204. In accordance with some embodiments, the first insulating layer 206 may include molding compound, epoxy, another suitable encapsulation material, or a combination thereof, but it is not limited thereto. In accordance with some embodiments, the first insulating layer 206 may be formed by a compression molding process, a transfer molding process, another applicable process, or a combination thereof. In accordance with some embodiments, the first insulating layer 206 may undergo a molding process in a liquid or semi-liquid state, and then be cured.

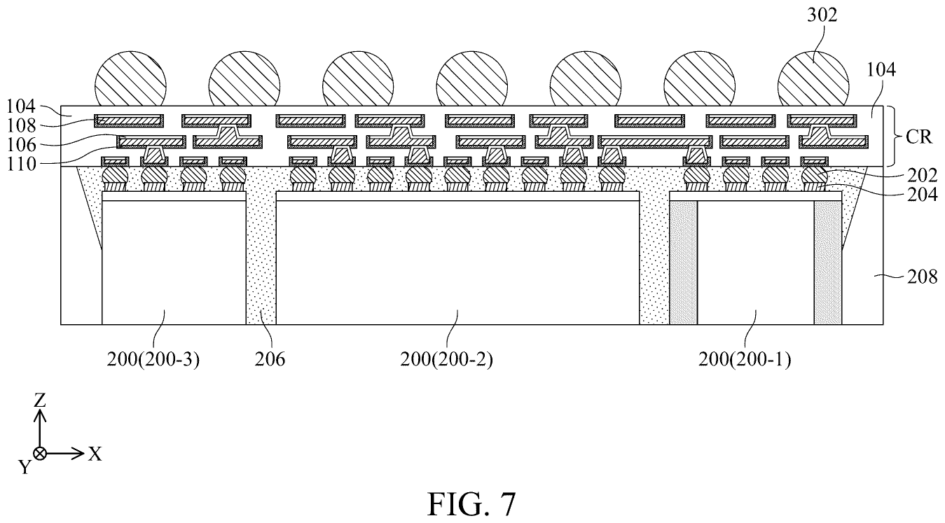

Then, referring to FIG. 7, a second insulating layer 208 may be formed to surround the first insulating layer 206 and the electronic units 200. In accordance with some embodiments, the second insulating layer 206 and the first insulating layer 204 may be formed of the same or similar material. Then, the substrate 102 may be removed, and a plurality of second connecting elements 302 may be formed on the redistribution layer CR. In accordance with some embodiments, the second connecting elements 302 and the first connecting elements 202 are disposed on opposite sides of the redistribution layer CR. In accordance with some embodiments, the second connecting elements 302 may be electrically connected to the metal layer 108 of the redistribution layer CR. In accordance with some embodiments, the material and method of forming the second connecting element 302 are the same or similar to those of the first connecting element 202, and thus will not be repeated here.

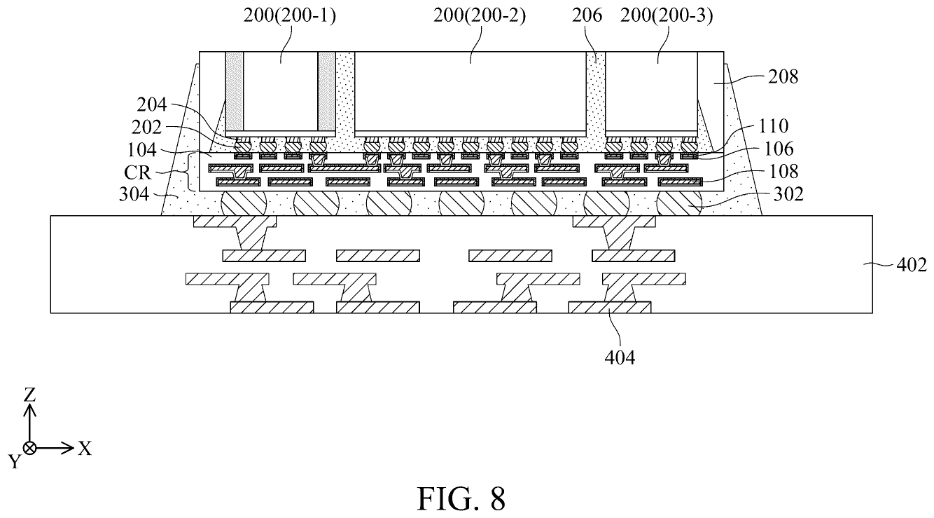

Next, referring to FIG. 8, a second substrate 402 is provided, and the aforementioned structure may be disposed on the second substrate 402. Specifically, the second connecting elements 302 may be disposed between the redistribution layer CR and the second substrate 402. In other words, the redistribution layer CR may serve as an interposer. In accordance with some embodiments, the second substrate 402 may also include one or more conductive layers 404. In accordance with some embodiments, the second connecting elements 302 may be electrically connected to the conductive layer 404 of the second substrate 402. In accordance with some embodiments, the second substrate 402 may include a redistribution layer, a through-glass-via substrate, a printed circuit board, another suitable substrate, or a combination thereof.

As shown in FIG. 8, a third insulating layer 304 may be formed to surround the first insulating layer 206, the second insulating layer 208, the redistribution layer CR and the second connecting elements 302. The third insulating layer 304 may be used to fill the gaps between the second connecting elements 302 to provide structural support. In accordance with some embodiments, the third insulating layer 304 and the first insulating layer 204 may be formed of the same or similar material.

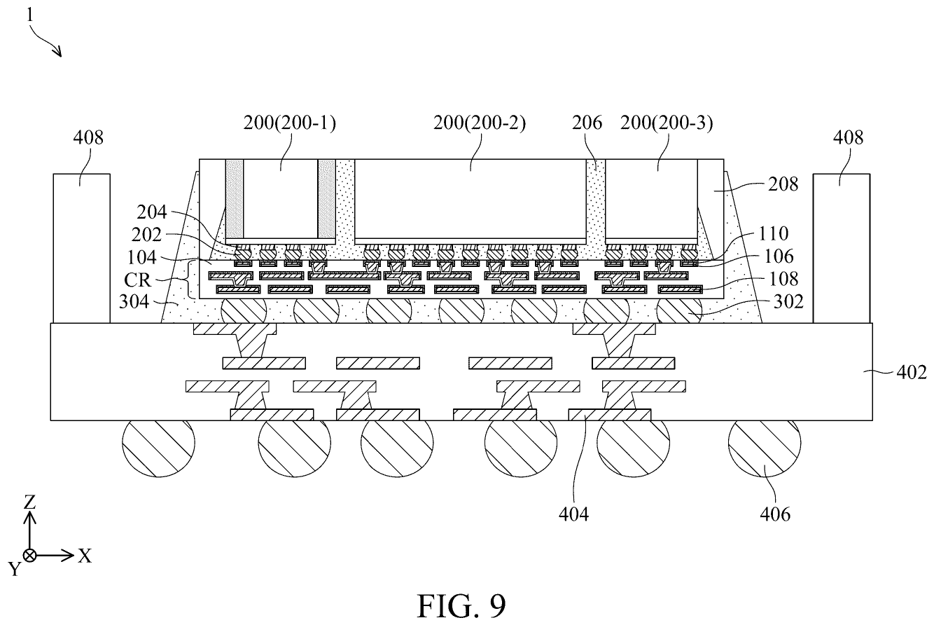

Then, referring to FIG. 9, a supporting element 408 may be formed on the second substrate 402. The supporting element 408 may have a ring shape in a top view. In accordance with some embodiments, the supporting element 408 may include a frame, a spacer, a sealant, or a combination thereof. The material of the supporting element 408 may include an insulating material, a conductive material, or other suitable materials.

Moreover, as shown in FIG. 9, a plurality of third connecting elements 406 may be formed on the second substrate 402. In accordance with some embodiments, the third connecting elements 406 and the second connecting elements 302 are disposed on opposite sides of the second substrate 402. The third connecting elements 406 may be electrically connected to the conductive layer 404 of the second substrate 402. In accordance with some embodiments, the third connecting elements 406 may include microbumps, controlled collapse chip connection (C4) bumps, conductive pillars, solder paste, ball grid array (BGA) balls, frame board, another suitable connecting component, or a combination thereof. In accordance with some embodiments, the material of the third connecting element 406 may be formed of metal, including tungsten, titanium, tantalum, ruthenium, cobalt, copper, aluminum, platinum, tin, silver, gold, an alloy of the aforementioned metals, another suitable conductive material, or a combination thereof, but it is not limited thereto.

As shown in FIG. 9, the electronic device 1 formed by the aforementioned method includes the second substrate 402, the electronic unit 200 on the second substrate 402, the redistribution layer CR between the second substrate 402 and the electronic unit 200, the first connecting elements 202 between the electronic unit 200 and the redistribution layer CR, and the second connecting elements 302 between the redistribution layer CR and the second substrate 402. The first connecting elements 202 electrically connects the electronic unit 200 and the redistribution layer CR, and the second connecting elements 302 electrically connects the redistribution layer CR and the second substrate 402. The redistribution layer CR may have the structure based on the aforementioned semiconductor structure 10, the aforementioned semiconductor structure 20 or the aforementioned semiconductor structure 30.

To summarize the above, in accordance with the embodiments of the present disclosure, the provided semiconductor structure can be a redistribution layer structure. The semiconductor structure includes a barrier layer disposed on the side surfaces and/or upper surface of the metal layer. The barrier layer can reduce metal diffusion occurring between the metal layers in the redistribution layer, thereby improving the reliability of the semiconductor structure. Moreover, with the specific configuration of the barrier layer and the dielectric layer, the process cost and difficulty of the semiconductor structure can also be decreased.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a first dielectric layer;
a first metal layer disposed on the first dielectric layer; and
a barrier layer on an upper surface and side surfaces of the first metal layer and comprising a first via hole above the first metal layer,
wherein the barrier layer is a nitrogen-containing layer.

2. The semiconductor structure as claimed in claim 1, wherein a thickness of the barrier layer is greater than 10 nm.

3. The semiconductor structure as claimed in claim 2, wherein the thickness of the barrier layer is between 10 nm and 30 nm.

4. The semiconductor structure as claimed in claim 1, wherein a nitrogen content of the barrier layer is within a range of 5 to 15 wt %.

5. The semiconductor structure as claimed in claim 1, further comprising a second dielectric layer disposed on the first dielectric layer, wherein the second dielectric layer comprises a second via hole connected to the first via hole.

6. The semiconductor structure as claimed in claim 5, further comprising a second metal layer disposed in the first via hole and the second via hole.

7. An electronic device, comprising:
a substrate;
an electronic unit on the substrate;
a redistribution layer disposed between the substrate and the electronic unit,
wherein the redistribution layer comprises a semiconductor structure, the semiconductor structure comprising:
a first dielectric layer;
a first metal layer disposed on the first dielectric layer; and
a barrier layer covering an upper surface and side surfaces of the first metal layer and comprising a first via hole above the first metal layer,
wherein the barrier layer is a nitrogen-containing layer.

8. The electronic device as claimed in claim 7, wherein a thickness of the barrier layer is greater than 10 nm.

9. The electronic device as claimed in claim 7, wherein a nitrogen content of the barrier layer is within a range of 5 to 15 wt %.

10. A method of forming a semiconductor structure, comprising:
forming a first dielectric layer;
forming a first metal layer on the first dielectric layer;
cleaning the first metal layer;
forming a barrier layer on side surfaces and an upper surface of the first metal layer, wherein the barrier layer is a nitrogen-containing layer; and
forming a first via hole above the first metal layer.

11. The method of forming a semiconductor structure as claimed in claim 10, wherein a thickness of the barrier layer is greater than 10 nm.

12. The method of forming a semiconductor structure as claimed in claim 11, wherein the thickness of the barrier layer is between 10 nm and 30 nm.

13. The method of forming a semiconductor structure as claimed in claim 10, wherein the step of forming the first via hole comprises:
forming a second dielectric layer on the first dielectric layer and covering the first metal layer; and
removing a portion of the barrier layer to form the first via hole above the first metal layer.

14. The method of forming a semiconductor structure as claimed in claim 13, further comprising:
removing a portion of the second dielectric layer to form a second via hole, wherein the second via hole is connected to the first via hole; and
forming a second metal layer in the first via hole and the second via hole.

15. The method of forming a semiconductor structure as claimed in claim 10, wherein the step of cleaning the first metal layer comprises removing a naturally formed oxide on the upper surface and the side surfaces of the first metal layer.

16. The method of forming a semiconductor structure as claimed in claim 15, wherein the step of cleaning the first metal layer comprises a wet etching process.

17. The method of forming a semiconductor structure as claimed in claim 15, wherein the step of cleaning the first metal layer comprises a plasma etching process.

18. The method of forming a semiconductor structure as claimed in claim 10, wherein the step of forming the barrier layer comprises a plasma treatment using a N₂ plasma.

19. The method of forming a semiconductor structure as claimed in claim 18, wherein in the step of forming the barrier layer, the barrier layer is formed from the first metal layer on the side surfaces and the upper surface of the first metal layer.

20. The method of forming a semiconductor structure as claimed in claim 17, wherein the step of forming the barrier layer comprises an atomic layer deposition using a nitrogen source.
